(19) United States
(12) Patent Application Publication
(10) Pub. No.: US 2002/0017683 A1
(43) Pub. Date: Feb. 14, 2002

(54) High voltage semiconductor device having high breakdown voltage isolation region

(75) Inventor: Chang-Ki Jeon, Kimpo-city (KR)

Correspondence Address: ROTHWELL, FIGG, ERNST & MANBECK, P.C., 555 13TH STREET, N.W., SUITE 701, EAST TOWER, WASHINGTON, DC, 20004, US

(73) Assignee: Fairchild Korea Semiconductor Ltd., Puchon (KR)

(21) Appl. No.: 09/824,804

(22) Filed: Apr. 4, 2001

(30) Foreign Application Priority Data
Aug. 4, 2000 (KR) 2000-45270

(51) Int. Cl. H01L 29/76; H01L 29/94

(52) U.S. Cl. 257/339; 257/335

(57) ABSTRACT

A high voltage semiconductor device having a high breakdown voltage isolation region, in which the high breakdown voltage isolation region and a junction termination including a lateral DMOS transistor are formed between a high voltage region and a low voltage region. The lateral DMOS transistor and the high breakdown voltage isolation region are formed on a structure in which a semiconductor substrate of a first conductivity type and an epitaxial layer of a second conductivity type are sequentially formed. The epitaxial layers in the high breakdown voltage isolation region, the lateral DMOS transistor and the high voltage region are isolated from each other by first diffusion regions of a first conductivity type, which are formed between a certain depth of the semiconductor substrate and a certain depth of the epitaxial layer. Also, in this high voltage semiconductor device, a buried layer of a second conductivity type is formed between the semiconductor substrate of a first conductivity type and the epitaxial layer of a second conductivity type in each of the lateral DMOS transistor and the high voltage region.

### BACKGROUND OF THE INVENTION

1. Field of the Invention

The present invention relates to a high voltage semiconductor device, and more particularly, to a high voltage semiconductor device having a high breakdown voltage isolation region.

2. Description of the Related Art

FIG. 1 schematically shows a conventional high voltage semiconductor device which drives a power device such as a power MOSFET or insulated gate bipolar transistor (IGBT). Referring to FIG. 1, the high voltage semiconductor device includes a low voltage region 110 and a high voltage region 120 enclosed by the low voltage region 110. A junction termination 131 is interposed between the low voltage region 110 and the high voltage region 120. An n-type lateral DMOS transistor 132 is formed within the low voltage region 110, and a p-type high voltage MOS transistor 133 is formed within the high voltage region 120.

A signal is transmitted from the low voltage region 110 to the high voltage region 120 via the n-type lateral DMOS transistor 132 and the junction termination 131. A signal is transmitted from the high voltage region 120 to the low voltage region 110 via the p-type high voltage MOS transistor 133 and the junction termination 131.

FIG. 2 shows another example of a conventional high voltage semiconductor device, and FIG. 3 is a cross-sectional view of the device of FIG. 2 taken along line III-III′. As shown in FIGS. 2 and 3, the high voltage semiconductor device includes a low voltage region 210 and a high voltage region 220. The high voltage region 220 is isolated like an island and surrounded by the low voltage region 210. A junction termination is interposed between the high and low voltage regions 210 and 220. A lateral DMOS transistor 231 for signal transmission is formed on part of the junction termination, and a high breakdown isolation region 232 is interposed between the lateral DMOS transistor 231 and the high voltage region 220.

The DMOS transistor 231 includes a p-type semiconductor substrate 301, a first n-type diffusion region 302a, a second n-type diffusion region 302b, an n-type source/drain region 303, a first p-type diffusion region 304, a p⁺-type diffusion region 305, a gate insulating layer 306, a gate electrode 307, a source electrode 308 and a drain electrode 309. The drain electrode 309 is extended up to the high breakdown isolation region 232. The high voltage region 220 includes a third n-type diffusion region 310a, a second p-type diffusion region 311 and a p⁺-type diffusion region 305. In particular, the drain electrode 309 of the DMOS transistor 231 contacts the p⁺-type diffusion region 305, and another p⁺-type diffusion region 305 contacts a conductive layer 312. Typically, the conductive layer 312 is used as a passage for transferring a signal from the low voltage region 210 to the control circuit (not shown) of the high voltage region 220.

In this semiconductor device, when a predetermined voltage or more is applied to the gate electrode 307, the n-channel DMOS transistor 231 is turned on. When the DMOS transistor 231 is turned on, the potential difference between the conductive layer 312 and the drain electrode 309 occurs due to the flow of current flowing through the p-type diffusion region 311. By reading the potential difference, a logic signal applied to the gate electrode 307 is transferred as an output signal, which has a displaced potential level, to the high voltage region 220.

According to structures such as the above-described conventional high voltage semiconductor device, when high voltage, for example, 600V, is applied to the drain electrode 309, the space between the second and third n-type diffusion regions 302b and 310a is easily depleted since it is a p-type low concentration region. Accordingly, the potential lines between the two n-type diffusion regions 302b and 310a are overlapped by each other, so that the breakdown characteristics can be improved. Also, since the structures are self-shielding structures, an interconnection line traversed by signals passes through the p-type semiconductor substrate 301 not through a junction termination. Thus, in this case, the density of the interconnection line increases and the manufacturing process for semiconductor devices is simplified, compared to the case when an interconnection line passes through a junction termination.

However, in the above-described structures, when other devices such as MOS transistors or bipolar transistors are formed within the high voltage region 220, the total characteristics of a device are degraded. For example, when an npn bipolar transistor is formed within the high voltage region 220, there are no n⁺-type buried layers, so that the current driving capability is degraded. Also, base current leaks toward the semiconductor substrate 301, so that a current gain decreases. Furthermore, a p-type well region having a high impurity concentration must be formed to form an n-type MOS transistor within the third n-type diffusion region 310a. However, when the impurity concentration of the p-type well region increases, a threshold voltage also increases proportionally. The third n-type diffusion region 310a must have a high concentration and a deep junction in order to prevent occurrence of punch through between the p-type well region and the semiconductor substrate 301.

Furthermore, the above structures includes only the DMOS transistor 231 not high voltage p-type MOS transistor. Therefore, signals can be sent from a low voltage region to a high voltage region, but cannot be sent from a high voltage region to a low voltage region.

### SUMMARY OF THE INVENTION

To solve the above problems, it is an object of the present invention to provide a high voltage semiconductor device having a high breakdown isolation region, which can transmit signals from a high voltage region to a low voltage region in a structure in which various devices can be added while guaranteeing a high breakdown voltage and preventing a degradation in the device characteristics.

To achieve the above object of the present invention, there is provided a high voltage semiconductor device having a high breakdown voltage isolation region and a junction termination including a lateral DMOS transistor between a high voltage region and a low voltage region, according to an embodiment of the present invention, the device including: a semiconductor substrate of a first conductivity type; an epitaxial layer of a second conductivity type formed on the semiconductor substrate; a first diffusion region of a first conductivity type for isolation formed in each of the lateral DMOS transistor and the high breakdown voltage isolation region; a second diffusion region of a first conductivity type formed on the surface portion of the epitaxial layer in the lateral DMOS transistor to be adjacent to the first diffusion region of the first conductivity type; a source region of a second conductivity type formed within the second diffusion region of the first conductivity type; a drain region of a second conductivity type formed on the surface of the epitaxial layer in the lateral DMOS transistor to be isolated a predetermined interval apart from the source region of a second conductivity type; a resistance unit formed in the high voltage region for transferring a signal from the lateral DMOS transistor to the high voltage region; a gate insulating layer formed on the channel region of the second diffusion region of a first conductivity type in the lateral DMOS transistor; a gate electrode formed on the gate insulating layer; a source electrode formed to contact the source region of a second conductivity type; and a drain electrode which contacts the drain region of a second conductivity type and is formed to be connected to the resistance unit via the high breakdown voltage isolation region.

Preferably, the first diffusion region includes: a buried layer of a first conductivity type formed on the interface between the semiconductor substrate and the epitaxial layer in the lateral DMOS transistor and the high breakdown voltage isolation region; and an impurity region of a first conductivity region formed on the buried layer of a first conductivity type to be adjacent to the buried layer and the second diffusion region of a first conductive type.

In this high voltage semiconductor device, preferably, a buried layer of a second conductivity type is formed between the semiconductor substrate and the epitaxial layer within the high voltage region. In this case, it is preferable that the impurity concentration in the buried layer of a second conductivity type is higher than the impurity concentration in the epitaxial layer of a second conductivity type.

In this high voltage semiconductor device, preferably, a buried layer of a second conductivity type is further formed between the semiconductor substrate and the epitaxial layer within the lateral DMOS transistor to be isolated a predetermined interval apart from the drain region of a second conductivity type. In this case, it is preferable that the impurity concentration in the buried layer of a second conductivity type is higher than the impurity concentration in the epitaxial layer of a second conductivity type.

A top region of a first conductivity type can be further formed between the source region of a second conductivity type and the drain region of a second conductivity type, on the surface of the epitaxial layer of the lateral DMOS transistor.

A top region of a first conductivity type can be further formed on the surface of the epitaxial layer in the high breakdown voltage isolation region to be adjacent to the first diffusion region of a first conductivity type.

It is preferable that the resistance unit includes: a third diffusion region of a first conductivity type formed on the surface of the epitaxial layer in the high voltage region; and two high concentration regions of a first conductivity type formed on the surface of the third diffusion region of a first conductivity type so that the two high concentration regions are isolated from each other. In this case, preferably, one of the two high concentration regions of a first conductivity type is connected to the drain electrode, and a conductive layer connected to the high voltage region while contacting the other high concentration region of a second conductivity type not connected to the drain electrode is further included.

Also, preferably, the first conductivity type is a p type, and the second conductivity type is an n type.

To achieve the above objective of the present invention, there is provided a high voltage semiconductor device having a high voltage MOS transistor of a first conductivity type and a high breakdown voltage isolation region between a high voltage region and a low voltage region, according to another embodiment of the present invention, the device including: a semiconductor substrate of a first conductivity type; an epitaxial layer of a second conductivity type formed on the semiconductor substrate; a first diffusion region of a first conductivity type for isolation formed in each of the high voltage region and the high breakdown voltage isolation region; a buried layer of a second conductivity type formed between the semiconductor substrate and the epitaxial layer in each of the high voltage MOS transistor and the low voltage region; a source region of a first conductivity type formed a predetermined interval apart over the second buried layer of a second conductivity type in the high voltage MOS transistor; a drain region of a first conductivity type formed on the surface of the epitaxial layer in the high voltage MOS transistor to be isolated a predetermined interval from the source region of a first conductivity type; a resistance unit formed in the low voltage region for transferring a signal from the high voltage MOS transistor to the low voltage region; a gate insulating layer formed on a channel region on the surface of the epitaxial layer in the high voltage MOS transistor; a gate electrode formed on the gate insulating layer; a source electrode formed to contact the source region of a first conductivity type; and a drain electrode which contacts the drain region of a first conductivity type and is formed to be connected to the resistance unit via the high breakdown voltage isolation region.

Preferably, the first diffusion region includes: a buried layer of a first conductivity type formed on the interface between the semiconductor substrate and the epitaxial layer in the high voltage MOS region and the high breakdown voltage isolation region; and an impurity region of a first conductivity region formed on the buried layer of a first conductivity type.

It is preferable that the impurity concentration in the buried layer of a second conductivity type is higher than the impurity concentration in the epitaxial layer of a second conductivity type.

Preferably, a top region of a first conductivity type is further formed on the surface of the epitaxial layer of the high voltage MOS transistor so that it is isolated a predetermined interval from the source region of a first conductivity type and covers the drain region of a first conductivity type.

It is also preferable that the resistance unit includes: a second diffusion region of a first conductivity type formed on the surface of the epitaxial layer in the low voltage region; and two high concentration regions of a first conductivity type formed on the surface of the second diffusion region of a first conductivity type so that the two high concentration regions are isolated from each other. In this case, preferably, one of the two high concentration regions of a first conductivity type is connected to the drain electrode, and a conductive layer connected to the high voltage region while contacting the other high concentration region of a second conductivity type not connected to the drain electrode is further included.

Preferably, the first conductivity type is a p type, and the second conductivity type is an n type.

### BRIEF DESCRIPTION OF THE DRAWINGS

The above objective and advantages of the present invention will become more apparent by describing in detail preferred embodiments thereof with reference to the attached drawings in which:

FIG. 1 is a schematic view of a high voltage semiconductor device which drives a power device such as a power MOS field emission transistor (MOSFET) or an insulating gate bipolar transistor (IGBT);

FIG. 2 is a schematic view of another example of the high voltage semiconductor device of FIG. 1;

FIG. 3 is a cross-sectional view of FIG. 2 taken along line III-III′;

FIG. 4 is a cross-sectional view of a high voltage semiconductor device having a high breakdown voltage isolation region, according to an embodiment of the present invention;

FIG. 5 is a cross-sectional view of FIG. 4 taken along line V-V′;

FIG. 6 is a cross-sectional view of a high voltage semiconductor device having a high breakdown voltage isolation region, according to another embodiment of the present invention;

FIG. 7 is a cross-sectional view of FIG. 6 taken along line VII-VII′;

FIGS. 8 through 14 are cross-sectional views illustrating a method of manufacturing a high voltage semiconductor device having a high breakdown voltage isolation region, according to an embodiment of the present invention; and

FIGS. 15 through 21 are cross-sectional views illustrating a method of manufacturing a high voltage semiconductor device having a high breakdown voltage isolation region, according to another embodiment of the present invention.

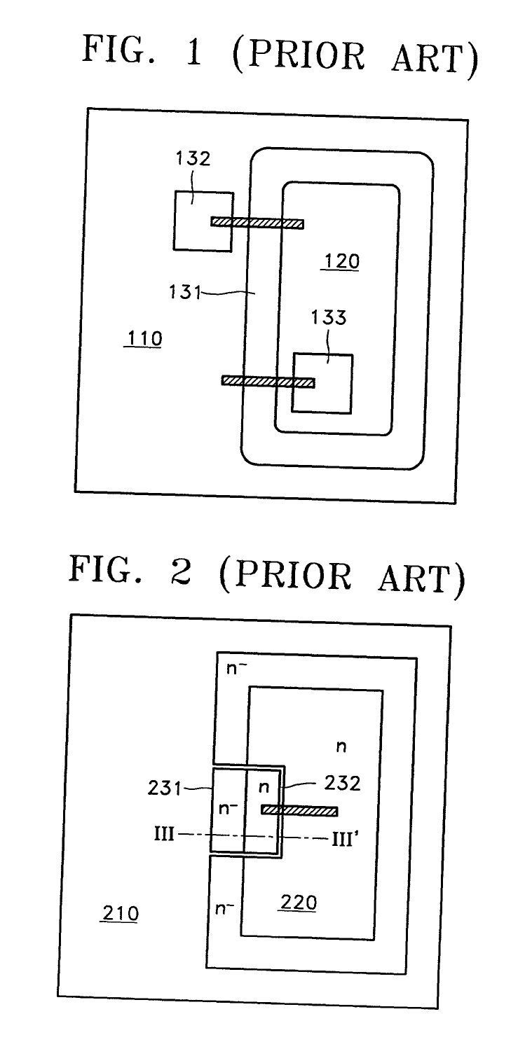

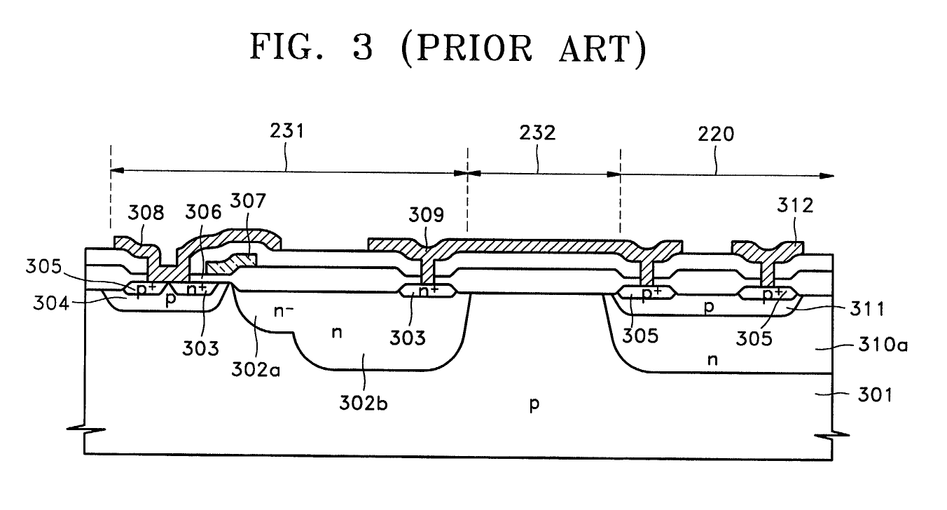

### DESCRIPTION OF THE PREFERRED EMBODIMENTS

Hereinafter, embodiments of the present invention will be described in detail with reference to the attached drawings. However, the embodiments of the present invention can be modified into various other forms, and the scope of the present invention must not be interpreted as being restricted to the embodiments. The embodiments are provided to more completely explain the present invention to those skilled in the art. In the drawings, the thicknesses of layers or regions are exaggerated for clarity. Like reference numerals in the drawings denote the same members. Also, when it is written that a layer is formed “on” another layer or a substrate, the layer can be formed directly on the other layer or the substrate, or other layers can intervene therebetween.

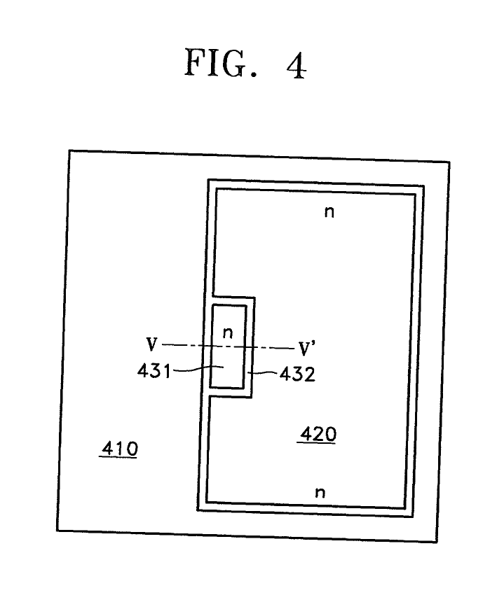

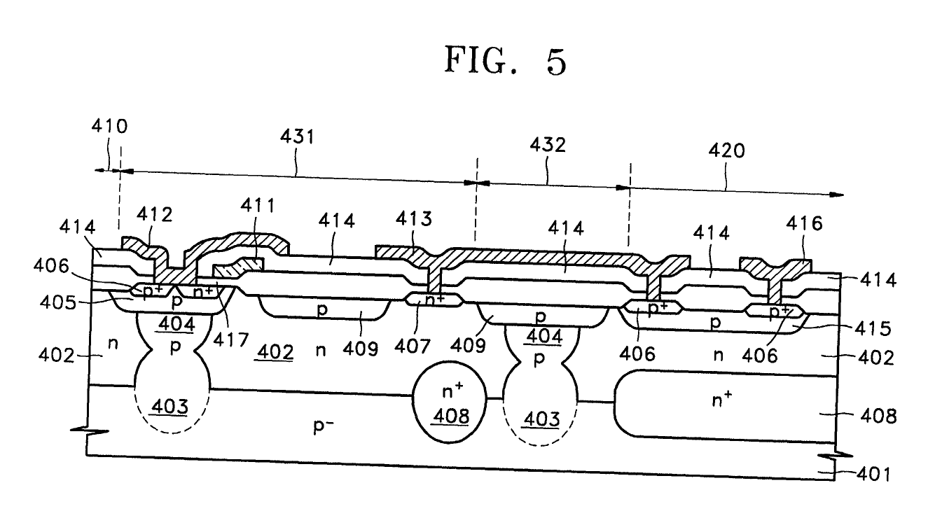

FIG. 4 is a cross-sectional view of a high voltage semiconductor device having a high breakdown voltage isolation region, according to an embodiment of the present invention. FIG. 5 is a cross-sectional view of FIG. 4 taken along line V-V′.

Referring to FIGS. 4 and 5, the high voltage semiconductor device includes a low voltage region 410 and a high voltage region 420. The high voltage region 420 is isolated like an island, and the high voltage region 410 is enclosed by the low voltage region 420. A junction termination is formed between the low and high voltage regions 410 and 420, and a lateral DMOS transistor 431 for signal transmission is formed on part of the junction termination. The lateral DMOS transistor 431 and the high voltage region 420 are isolated from each other by a high breakdown voltage isolation region 432.

The lateral DMOS transistor 431 includes a p⁻-type semiconductor substrate 401, an n-type epitaxial layer 402, first p-type diffusion regions 403 and 404, a second p-type diffusion region 405, p⁺-type diffusion regions 406, n⁺-type source/drain regions 407, an n⁺-type buried layer 408, a p-type top region 409, a gate insulating layer 417, a gate electrode 411, a source electrode 412 and a drain electrode 413. The first p-type diffusion regions 403 and 404 include a p-type buried layer 403 and a p-type impurity region 404.

That is, the n-type epitaxial layer 402 is formed on the p⁻-type semiconductor substrate 401, and the p-type buried layer 403 and the n⁺-type buried layer 408 are formed on the interface between the n-type epitaxial layer 402 and the p⁻-type semiconductor substrate 401. The p-type impurity region 404 is formed on the p-type buried layer 403. The second p-type diffusion region 405 is formed on the p-type impurity region 404, and serves as a well region in which a channel is formed. An n⁺-type source region 407 and a p⁺-type diffusion region 406 are formed on the surface of the second p-type diffusion region 405. An n⁺-type drain region 407 is formed on the surface of the n-type epitaxial layer 402 on the n⁺-type buried layer 408, isolated a predetermined interval apart from the n⁺-type buried layer 408. The source electrode 412 is formed so as to contact the n⁺-type diffusion region 406 and the n⁺-type source region 407, and the drain electrode 413 is formed so as to contact the n⁺-type drain region 407. The gate electrode 411 is formed on the gate insulating layer 417 formed on the channel region of the second p-type diffusion region 405. The electrodes are insulated from each other by an insulating layer 414.

In the high breakdown voltage isolation region 432, the drain electrode 413 extends on the insulating layer 414. As in the lateral DMOS transistor 431, a p-type buried layer 403 is formed on the interface between the n-type epitaxial layer 402 and the p⁻-type semiconductor substrate 401, and a p-type impurity region 404 is formed on the p-type buried layer 403. A p-type top region 409 is formed on the p-type impurity region 404.

The high voltage region 420 includes the p⁻-type semiconductor substrate 401, the n-type epitaxial layer 402 and a resistance unit. The resistance unit is used to transfer signals from the lateral DMOS transistor 431 to the high voltage region 420, and includes an n⁺-type buried layer 408, a third p-type diffusion region 415, a p⁺-type diffusion region 406 and a conductive layer 416.

That is, the n-type epitaxial layer 402 is formed on the p⁻-type semiconductor substrate 401, and the n⁺-type buried layer 408 is formed between them. The third p-type diffusion region 415 is formed on the surface of the n-type epitaxial layer 402, isolated a predetermined interval apart from the n⁺-type buried layer 408. Two isolated p⁺-type diffusion regions 406 are formed on the surface of the third p-type diffusion region 415. One p⁺-type diffusion region contacts the drain electrode 413 which extends from the DMOS transistor 431 to the high voltage region 420 via the high breakdown voltage isolation region 432, and the other contacts the conductive layer 416. Typically, the conductive layer 416 serves as a signal transferring passage to the control circuit (not shown) of the high voltage region 420.

In this semiconductor device, when a predetermined voltage or more is applied to the gate electrode 411, the n-channel DMOS transistor 431 is turned on. When the DMOS transistor 431 is turned on, a potential difference between the conductive layer 416 and the drain electrode 414 occurs by current flowing from the third p-type diffusion region 415. By reading the potential difference, a logic signal applied to the gate electrode 411 is transferred as an output signal, which has a displaced potential level, to the high voltage region 420.

The high voltage semiconductor device according to the present invention uses an epitaxial layer instead of a conventional well structure, so that it has the following effects. Firstly, a high electric field is applied to the n⁺-type buried layer 408 formed under the n⁺-type drain region 407 of the lateral DMOS transistor. Thus, during breakdown of the DMOS transistor, impact ionization first occurs on the n⁺-type buried layer 408 before it occurs on the surface region of the semiconductor substrate, thereby improving the reliability of a semiconductor device. Furthermore, although the high breakdown voltage isolation region 432 having a double isolation structure made up of the p-type buried layer 403 and the p-type impurity region 404 is not easily depleted since it has a greater concentration than that in conventional semiconductor devices, the potential lines between two regions are overlapped by each other, which prevents a high electrical field from being applied. Therefore, a sufficient breakdown voltage can be guaranteed only if the high breakdown voltage isolation region 432 does not have an extremely high concentration.

Secondly, the leakage current between the DMOS transistor 431 and the high voltage region 420 is reduced due to increases in the concentrations of the first p-type diffusion regions 403 and 404 and the p-type top region 409 in the lower portion of the high breakdown voltage isolation region 432.

Thirdly, various devices having good characteristics can be formed within the high voltage region 420. If a complementary MOS transistor is formed within the high voltage region 420, it is formed on the epitaxial layer 402. Thus, it is easy to control a threshold voltage. If a bipolar transistor is formed within the high voltage region 420, the current driving capability of the bipolar transistor is improved due to the presence of the n⁺-type buried layer 408, and leakage current to the semiconductor substrate 401 is reduced.

Fourthly, when a conventional well region is used, a predetermined voltage or more, for example, about 600V or more, cannot be used since there is a voltage limit by which the well region is depleted. On the other hand, a high voltage semiconductor device according to the present invention can be easily applied to high breakdown voltage products of about 1000V or more since there is an n⁺-type buried layer 408.

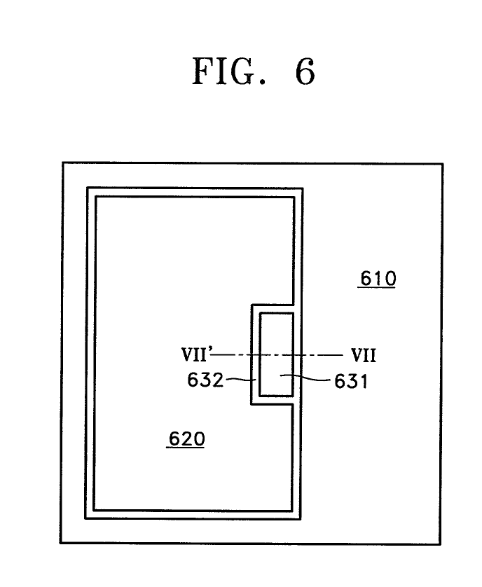

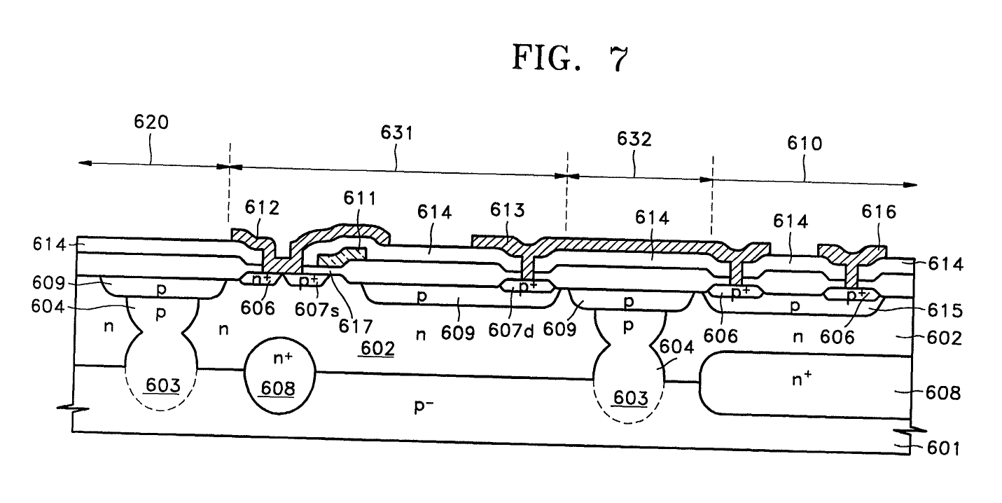

FIG. 6 is a cross-sectional view of a high voltage semiconductor device having a high breakdown voltage isolation region, according to another embodiment of the present invention. FIG. 7 is a cross-sectional view of FIG. 6 taken along line VII-VII′. Referring to FIGS. 6 and 7, this high voltage semiconductor device includes a low voltage region 610 and a high voltage region 620. The high voltage region 620 is isolated like an island, and the low voltage region 610 is formed to enclose the high voltage region 620. A junction termination is formed between the low and high voltage regions 610 and 620, and a high voltage MOS transistor 631 for signal transmission is formed on part of the junction termination. The high voltage MOS transistor 631 and the low voltage region 610 are isolated from each other by a high breakdown voltage isolation region 632.

The high voltage MOS transistor 631 includes a p⁻-type semiconductor substrate 601, an n-type epitaxial layer 602, n⁺-type diffusion regions 606, p⁺-type source/drain regions 607, an n⁺-type buried layer 608, a p-type top region 609, a gate insulating layer 617, a gate electrode 611, a source electrode 612 and a drain electrode 613.

That is, the n-type epitaxial layer 602 is formed on the p⁻-type semiconductor substrate 601, and the n⁺-type buried layers 608 are partially formed between the n-type epitaxial layer 602 and the p⁻-type semiconductor substrate 601. A p⁺-type source region 607s is formed on the surface of a portion of the n-type drift layer 602 on the n⁺-buried layer 608, isolated a predetermined interval apart from the n⁺-buried layer 608. A p⁺-type drain region 607d is formed on the surface of the n-type drift region 602, horizontally isolated a predetermined distance apart from the p⁺-type buried layer 608. The p-type top region 609 is formed so as to be isolated a predetermined distance apart from the p⁺-type source region 607s while covering the p⁺-type drain region 607d. The source electrode 612 is formed so as to contact the n⁺-type diffusion region 606 and the p⁺-type source region 607s, and the drain electrode 613 is formed so as to contact the p⁺-type drain region 607d. The gate electrode 611 is formed on the gate insulating layer 617 formed on the channel region of the n-type drift region 602. The electrodes are insulated from each other by an insulating layer 614.

In the high breakdown voltage isolation region 632, the drain electrode 613 extends on the insulating layer 614. The high breakdown voltage isolation region 632 also includes first p-type diffusion regions 603 and 604. That is, a p-type buried layer 603 is formed between the n-type epitaxial layer 602 and the p⁻-type semiconductor substrate 601, and a p-type impurity region 604 is formed on the p-type buried layer 603. A p-type top region 609 is formed on the p-type impurity region 604.

The low voltage region 610 includes the p⁻-type semiconductor substrate 601, the n-type epitaxial layer 602 and a resistance unit. The resistance unit is used to transfer signals from the high voltage MOS transistor 631 to the low voltage region 610, and includes an n⁺-type buried layer 608, a second p-type diffusion region 615, a p⁺-type diffusion region 606 and a conductive film 616.

That is, the n-type epitaxial layer 602 is formed on the p⁻-type semiconductor substrate 601, and the n⁺-type buried layer 608 is formed between them. The second p-type diffusion region 615 is formed on the surface of the n-type epitaxial layer 602, isolated a predetermined interval apart from the n⁺-type buried layer 608. Two isolated p⁺-type diffusion regions 606 are formed on the surface of the second p-type diffusion region 615. One p⁺-type diffusion region contacts the drain electrode 613 which extends from the high voltage p-type MOS transistor 631 to the low voltage region 610 via the high breakdown voltage isolation region 632, and the other contacts the conductive layer 616. Typically, the conductive layer 616 serves as a signal transferring passage to the control circuit (not shown) of the low voltage region 610.

The high voltage region 620 includes the p⁻-type semiconductor substrate 601, the n-type epitaxial layer 602, first p-type diffusion regions 603 and 604 and a p-type top region 609. The first p-type diffusion regions 603 and 604 are used for isolation, and includes a p-type buried layer 603, a p-type impurity region 604 and a p-type top region 609.

That is, the n-type epitaxial layer 602 is formed on the p⁻-type semiconductor substrate 601, and the p-type buried layer 603 is formed between them. The p-type impurity region 604 is formed on the p-type buried layer 603, and the p-type top region 609 is formed on the p-type impurity region 604.

In this semiconductor device, when a predetermined voltage or more is applied to the gate electrode 611, the high voltage p-type MOS transistor 631 is turned on. When the high voltage p-type MOS transistor 631 is turned on, a potential difference between the conductive layer 616 and the drain electrode 614 is formed by current flowing from the second p-type diffusion region 615. By reading the potential difference, a logic signal applied to the gate electrode 611 is transferred as an output signal, which has a displaced potential level, to the low voltage region 610.

The high voltage semiconductor device according to the present invention uses an epitaxial layer instead of a conventional well structure and additionally includes a buried layer, so that it has the following effects. Firstly, a high electric field is applied to the n⁺-type buried layer 608 formed under the p⁺-type drain region 607 of the high voltage p-type MOS transistor 631. Thus, during breakdown of the high voltage p-type MOS transistor 631, impact ionization first occurs on the n⁺-type buried layer 608 before it occurs on the surface region of the semiconductor substrate, thereby improving the reliability of the semiconductor device. Furthermore, although the high breakdown voltage isolation region 632 having a double isolation structure made up of the p-type buried layer 603 and the p-type impurity region 604 is not easily depleted since it has a greater concentration than that in conventional semiconductor devices, the potential lines between two regions are overlapped by each other, which prevents a high electrical field from being applied. Therefore, a sufficient breakdown voltage can be guaranteed only if the high breakdown voltage isolation region 632 does not have an extremely high concentration.

Secondly, the leakage current between the high voltage p-type MOS transistor 631 and the low voltage region 610 is reduced due to increases in the concentration of the p-type impurity region 404 in the lower portion of the high breakdown voltage isolation region 632. The leakage current between the high voltage p-type MOS transistor 631 and the high voltage region 620 is also reduced.

Thirdly, various devices having good characteristics can be formed within the low voltage region 610. If a complementary MOS transistor is formed within the low voltage region 610, it is formed on the epitaxial layer 602. Thus, it is easy to control a threshold voltage. If a bipolar transistor is formed within the low voltage region 610, the current driving capability of the bipolar transistor is improved due to the presence of the n⁺-type buried layer 608, and a leakage current to the semiconductor substrate 601 is reduced.

Fourthly, when a conventional well region is used, a predetermined voltage or more, for example, about 600V or more, cannot be used since there is a voltage limit by which the well region is depleted. On the other hand, a high voltage semiconductor device according to the present invention can be easily applied to high breakdown voltage products of about 1000V or more since there is an n⁺-type buried layer 608.

Fifthly, signals can be transferred to the low voltage region 610 via the resistance unit of the low voltage region 610 by applying a gate voltage to the gate electrode 611 of the high voltage p-type MOS transistor 631.

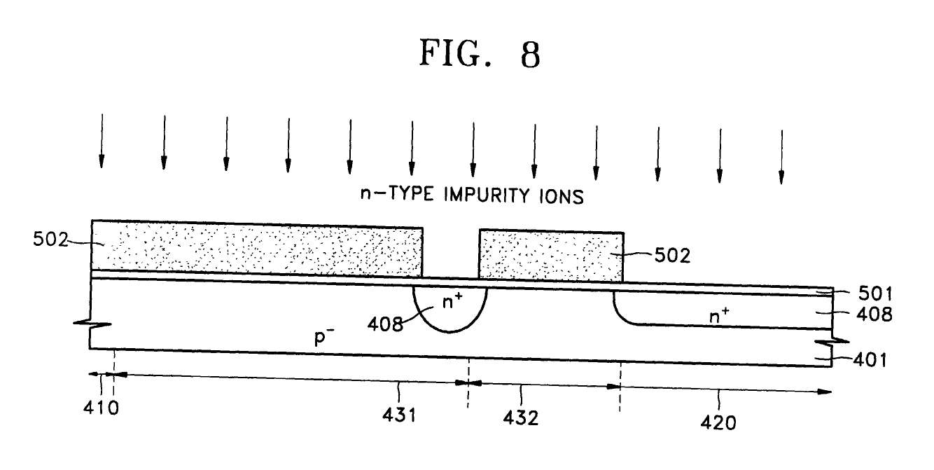

FIGS. 8 through 14 are cross-sectional views illustrating a method of manufacturing a high voltage semiconductor device having a high breakdown voltage isolation region, according to an embodiment of the present invention. Here, reference numeral 410 denotes a low voltage region, reference numeral 431 denotes a lateral DMOS transistor, reference numeral 432 denotes a high breakdown voltage isolation region, and reference numeral 420 denotes a high voltage region.

Referring to FIG. 8, first, a thermal oxide layer 501 of a thickness of about 2000 to 10000 Å to serve as an ion buffer layer is formed on a p⁻-type semiconductor substrate 401. A photoresist layer pattern 502 for forming an n⁺-type buried layer 408 is formed by performing exposure and development using a typical lithographic technique. Next, n-type impurity ions, for example, arsenic (As) ions or antimony (Sb) ions, are implanted using the photoresist layer pattern 502 as an ion implantation mask. After the photoresist layer pattern 502 is removed, an n⁺-type buried layer 408 is formed in each of the lateral DMOS transistor 431 and the high voltage region 420 by thermal oxidation and thermal diffusion.

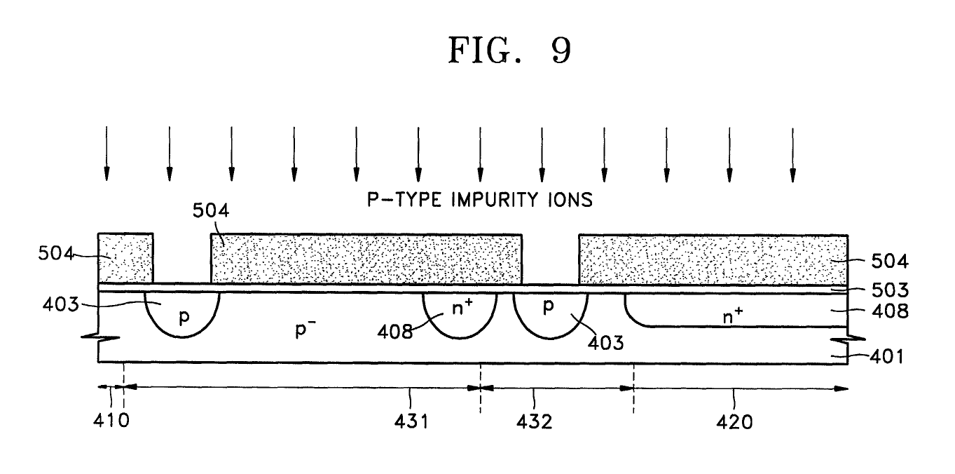

Referring to FIG. 9, a thermal oxide layer 503 having a thickness of about 200 to 1000 Å to serve as an ion buffer layer is formed after the thermal oxide layer 501 on the semiconductor substrate 401 is completely removed. A photoresist layer pattern 504 for forming a p-type buried layer 403 is formed by performing exposure and development using a typical lithographic technique. Next, p-type impurity ions, for example, boron (B) ions or BF₂ ions, are implanted using the photoresist layer pattern 504 as an ion implantation mask. After the photoresist layer pattern 504 is removed, a p-type buried layer 403 is formed in each of the lateral DMOS transistor 431 and the high breakdown voltage isolation region 432 by thermal diffusion.

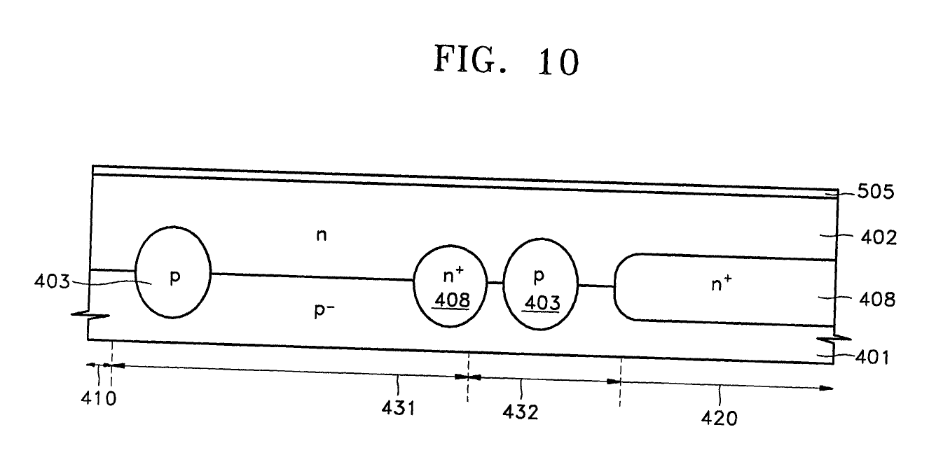

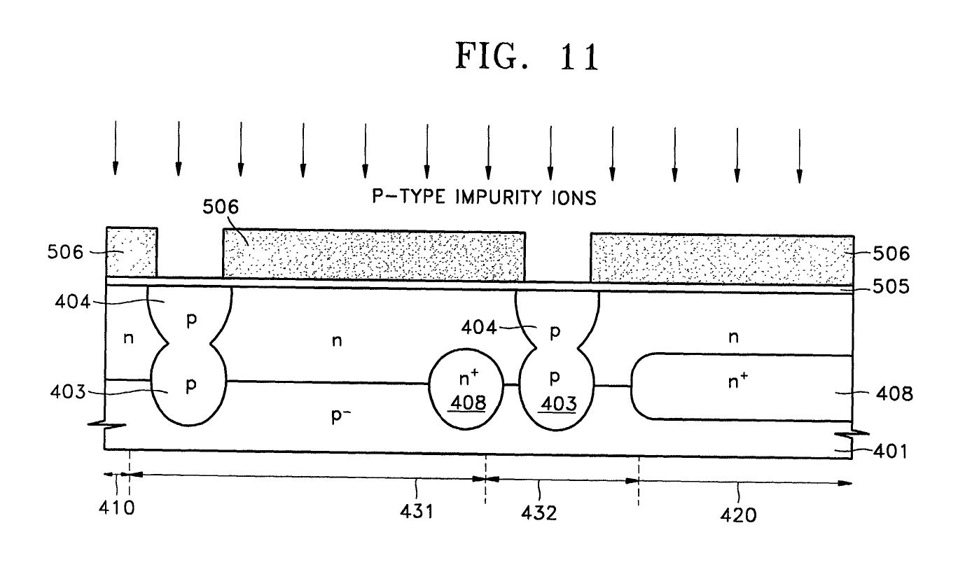

Referring to FIG. 10, the oxide layer on the semiconductor substrate 401 is completely removed, and then an n-type epitaxial layer 402 is grown at a specific resistance of about 0.5 to 10 Ωcm to a thickness of about 3-20 μm. Next, a thermal oxide layer 505 having a thickness of about 100 to 2000 Åis formed on the n-type epitaxial layer 402. While the thermal oxide layer 505 is being formed, the p-type buried layer 403 and the n⁺-type buried layer 408 are diffused toward the n-type epitaxial layer 402.

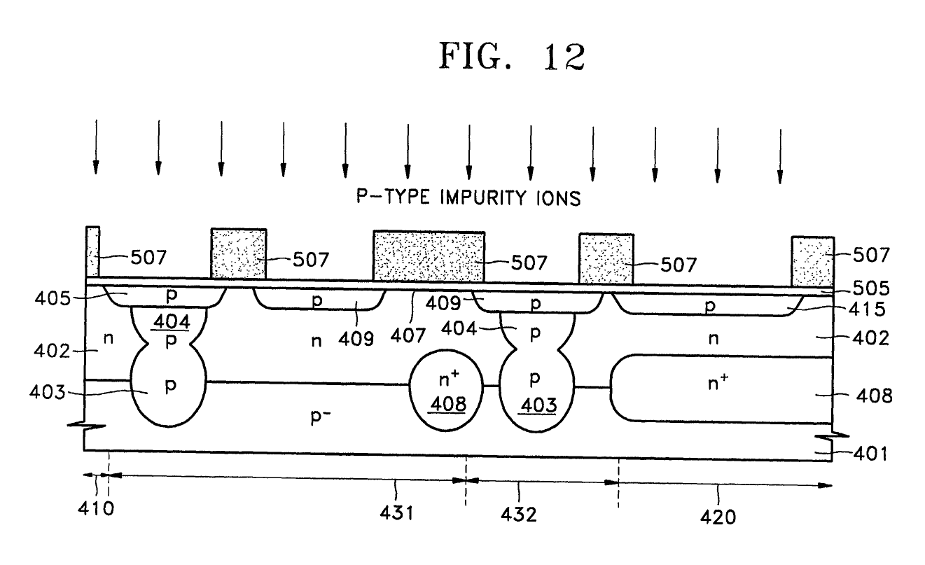

Referring to FIG. 11, a photoresist layer pattern 506 for forming a p-type impurity region 404 is formed by performing exposure and development using a typical lithographic technique. Then, p-type impurity ions, for example, boron (B) ions or BF₂ ions, are implanted using the photoresist layer pattern 506 as an ion implantation mask. Next, the photoresist layer pattern 506 is removed, and a p-type impurity region 404 is formed in each of the lateral DMOS transistor 431 and the high breakdown voltage isolation region 432 by thermal diffusion.

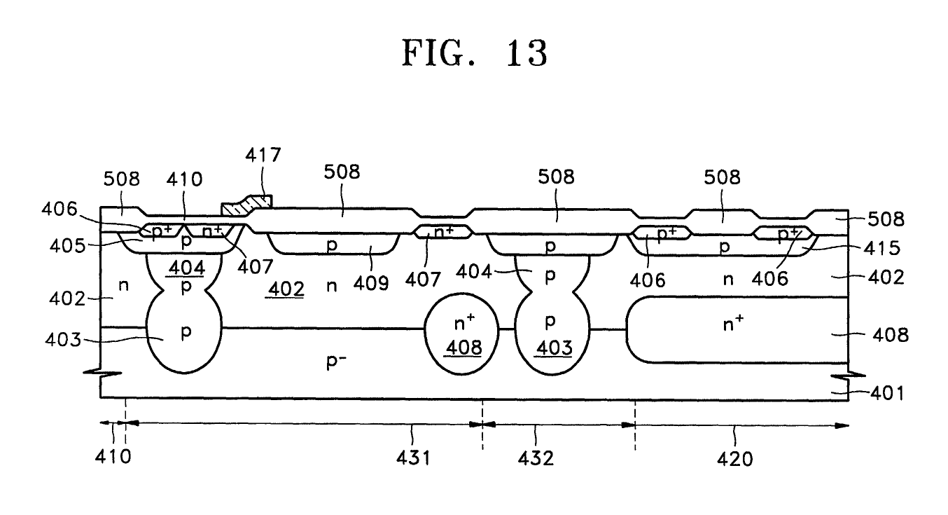

Referring to FIG. 12, a photoresist layer pattern 507 for forming a second p-type region 405, a third p-type diffusion region 415 and a p-type top region 409 is formed by exposure and development using a typical lithographic technique. Next, p-type impurity ions are implanted using the photoresist layer pattern 507 as an ion implantation mask. After the photoresist layer pattern 507 is removed, thermal diffusion is performed. Thus, a second p-type diffusion region 405 and a p-type top region 409 are formed in the lateral DMOS transistor 431, a p-type top region 409 is formed in the high breakdown voltage isolation region 432, and a third p-type diffusion region 415 is formed in the high voltage region 420.

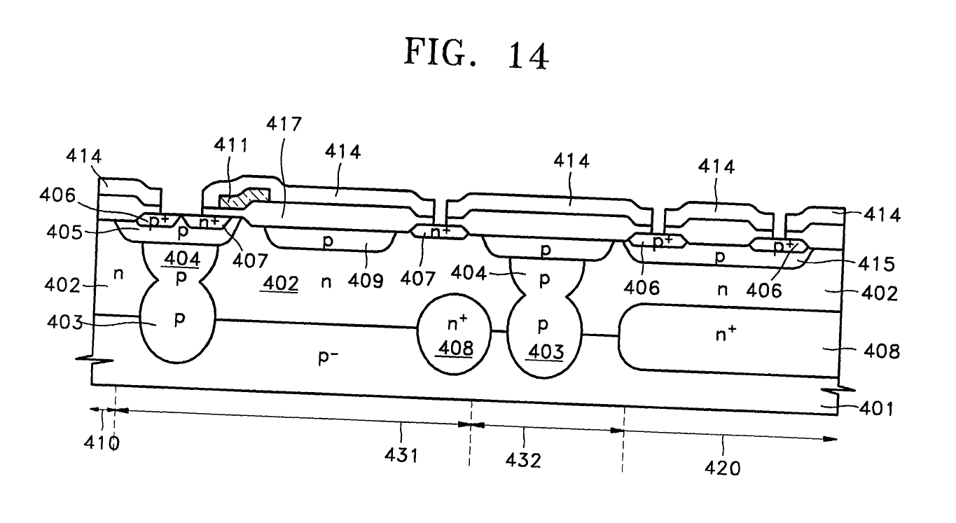

Referring to FIG. 13, oxide layers on the n-type epitaxial layer 402, the second p-type diffusion region 405, the p-type top region 409 and the third p-type diffusion region 415 are all removed. Thereafter, a thermal oxide layer (not shown) having a thickness of about 100 to 2000 Å is formed, and a nitride layer (not shown) having a thickness of about 100 to 2000 Å is formed on the thermal oxide layer. Then, a photoresist layer pattern (not shown) is formed on the nitride layer by exposure and development using a typical lithographic method. Exposed portions of the nitride layer are removed using the photoresist layer pattern as an etch mask, thereby forming a nitride layer pattern which exposes parts of the surface of the thermal oxide layer. Then, the photoresist layer pattern is removed, and thermal oxidation is performed using the nitride layer pattern as an oxide layer growth preventing layer. Accordingly, as shown in FIG. 13, a LOCOS (Local Oxidation on Substrate) region 508 for isolation is formed. After the LOCOS region 508 is formed, the nitride layer pattern is removed. Oxide layers between the LOCOS regions 508 are removed, and an oxide layer 410 to serve as a gate insulating layer is then formed.

Then, an impurity-doped conductive layer, for example, a polysilicon layer (not shown), is formed on the entire surface of the resultant structure. Then, the polysilicon layer is patterned to form a gate electrode 411. Though not shown in FIG. 13, a gate spacer can be formed on the sidewalls of the gate electrode 411 after the gate electrode 411 is formed.

Thereafter, n⁺-type source/drain regions 407 are formed in the lateral DMOS transistor 431 by a typical n-type impurity ion implantation and diffusion process. Then, a p⁺-type diffusion region 406 is formed in each of the lateral DMOS transistor 431 and the high voltage region 420 by a p-type impurity ion implantation and diffusion process.

Referring to FIG. 14, an insulating layer is formed on the entire surface of the resultant structure. Then, the insulating layer is patterned using a predetermined etch mask layer pattern. Formed insulating layer patterns 414 have apertures which expose the p⁺-type region 406 and the n⁺-type source/drain regions 407 in the DMOS transistor 431, and apertures which expose the two p⁺-type regions 406 in the high voltage region 420.

Thereafter, as shown in FIG. 5, a source electrode 412, a drain electrode 413 and a conductive layer 416 are formed. Here, the drain electrode 413 extends through the high breakdown voltage isolation region 432 and contacts one p⁺-type region 406 in the high voltage region 420, and the conductive layer 416 contacts the other p⁺-type region 406. In this way, the high voltage semiconductor device having a high breakdown voltage isolation region according to an embodiment of the present invention is completed.

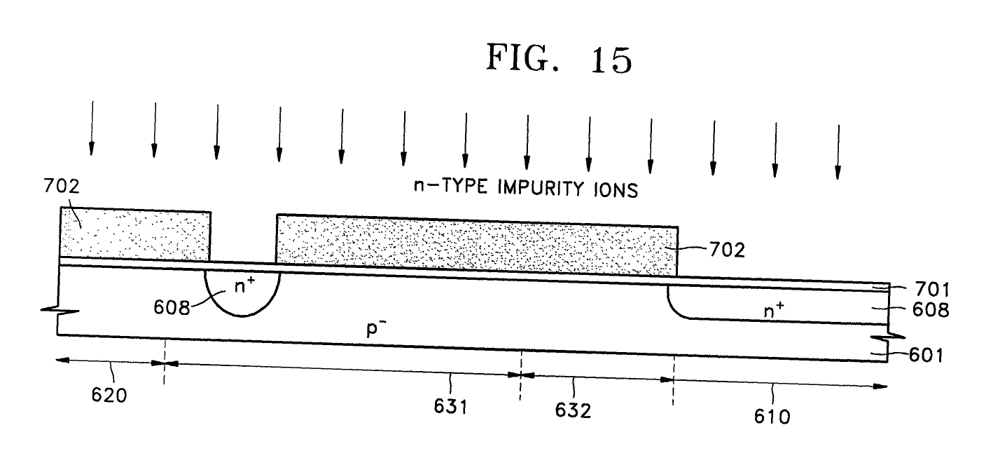

FIGS. 15 through 21 are cross-sectional views illustrating a method of manufacturing a high voltage semiconductor device having a high breakdown voltage isolation region, according to another embodiment of the present invention. Here, reference numeral 610 denotes a low voltage region, reference numeral 631 denotes a high voltage p-type MOS transistor, reference numeral 632 denotes a high voltage isolation region, and reference numeral 620 denotes a high voltage region.

Referring to FIG. 15, first, a thermal oxide layer 601 having a thickness of about 2000 to 10000 Å to serve as an ion buffer layer is formed on a p⁻-type semiconductor substrate 601. A photoresist layer pattern 702 for forming an n⁺-type buried layer 608 is formed by exposure and development using a typical lithographic technique. Next, n-type impurity ions, for example, arsenic (As) ions or antimony (Sb) ions, are implanted using the photoresist layer pattern 702 as an ion implantation mask. After the photoresist layer pattern 702 is removed, an n⁺-type buried layer 608 is formed in each of the high voltage p-type MOS transistor 631 and the low voltage region 610 by thermal oxidation and thermal diffusion.

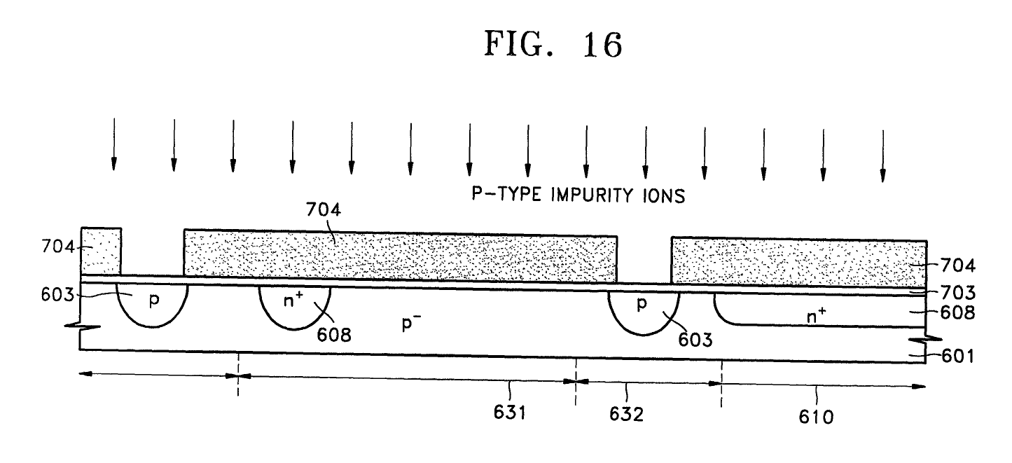

Referring to FIG. 16, a thermal oxide layer 703 having a thickness of about 200 to 1000 Å to serve as an ion buffer layer is formed after the thermal oxide layer on the semiconductor substrate 601 is completely removed. A photoresist layer pattern 704 for forming a p-type buried layer 603 is formed by exposure and development using a typical lithographic technique. Next, p-type impurity ions, for example, boron (B) ions or BF₂ ions, are implanted using the photoresist layer pattern 704 as an ion implantation mask. After the photoresist layer pattern 704 is removed, a p-type buried layer 603 is formed in each of the high voltage region 620 and the high breakdown voltage isolation region 632 by thermal diffusion.

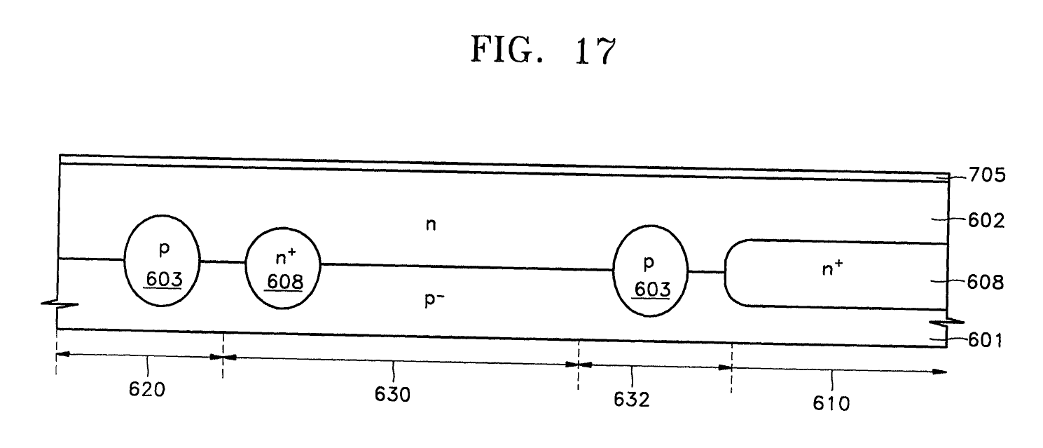

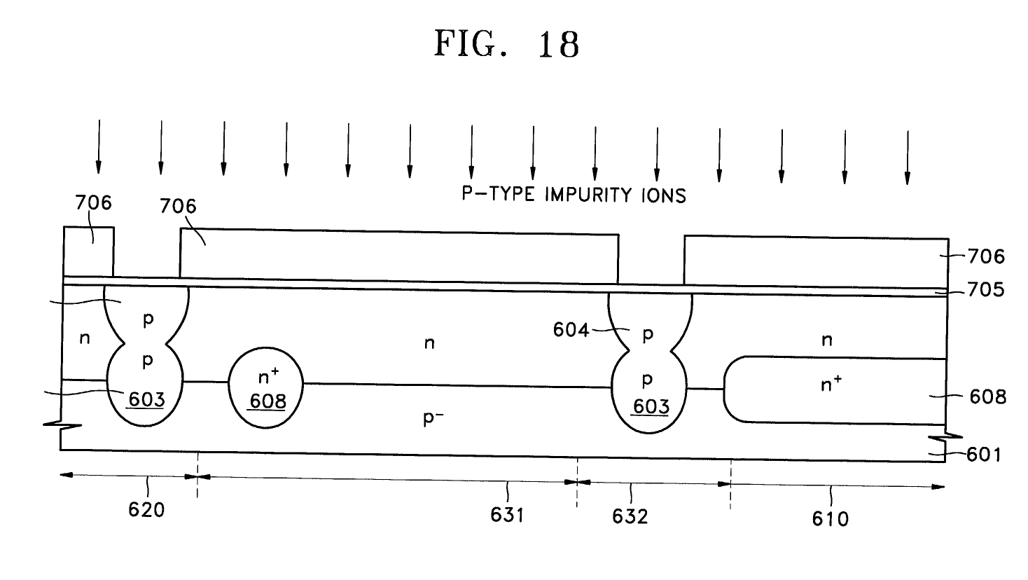

Referring to FIG. 17, the oxide layer on the semiconductor substrate 601 is completely removed, and then an n-type epitaxial layer 602 is grown at a specific resistance of about 0.5 to 10 Ωcm to a thickness of about 3-20 μm. Next, a thermal oxide layer 705 having a thickness of about 100 to 2000 Å is formed on the n-type epitaxial layer 602. While the thermal oxide layer 705 is being formed, the p-type buried layer 603 and the n⁺-type buried layer 608 are diffused toward the n-type epitaxial layer 602.

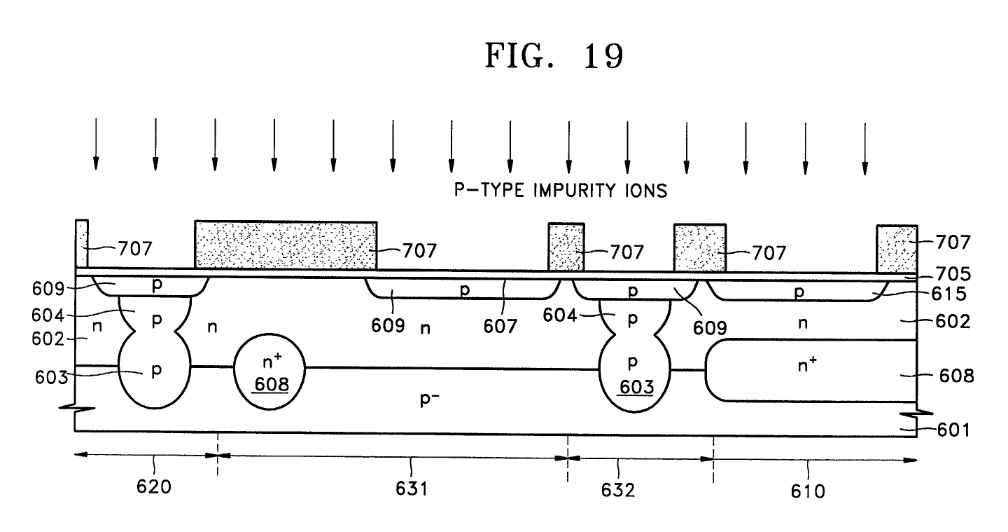

Referring to FIG. 18, a photoresist layer pattern 706 for forming a p-type impurity region 604 is formed by exposure and development using a typical lithographic technique. Then, p-type impurity ions, for example, boron (B) ions or BF₂ ions, are implanted using the photoresist layer pattern 706 as an ion implantation mask. Next, the photoresist layer pattern 706 is removed, and then a p-type impurity region 604 is formed in each of the high voltage region 620 and the high breakdown voltage isolation region 632 by thermal diffusion.

Referring to FIG. 19, a photoresist layer pattern 707 for forming p-type top regions 609 and a second p-type diffusion region 615 is formed by exposure and development using a typical lithographic technique. Next, p-type impurity ions are implanted using the photoresist layer pattern 707 as an ion implantation mask. After the photoresist layer pattern 707 is removed, thermal diffusion is performed. Thus, a the p-type top region 609 is formed in each of the high voltage region 620, the high voltage p-type MOS transistor 631 and the high breakdown voltage isolation region 632, and the second p-type diffusion region 615 is formed in the low voltage region 610.

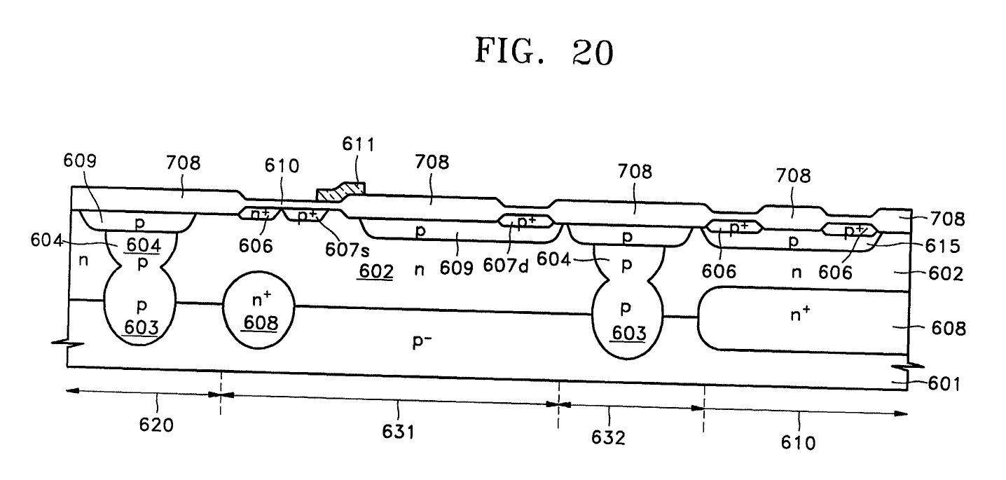

Referring to FIG. 20, oxide layers on the n-type epitaxial layer 602, the second p-type diffusion region 615 and the p-type top regions 609 are all removed. Thereafter, a thermal oxide layer (not shown) having a thickness of about 100 to 2000 Å is formed, and a nitride layer (not shown) having a thickness of about 100 to 2000 Å is formed on the thermal oxide layer. Then, a photoresist layer pattern (not shown) is formed on the nitride layer by exposure and development using a typical lithographic method. Exposed portions of the nitride layer are removed using the photoresist layer pattern as an etch mask, thereby forming a nitride layer pattern which exposes parts of the surface of the thermal oxide layer. Then, the photoresist layer pattern is removed, and thermal oxidation is performed using the nitride layer pattern as an oxide layer growth preventing layer. Accordingly, as shown in FIG. 20, a LOCOS (Local Oxidation on Substrate) region 708 for isolation is formed. After the LOCOS region 708 is formed, the nitride layer pattern is removed. Oxide layers between the LOCOS regions 708 are removed, and an oxide layer 617 to serve as a gate insulating layer is then formed.

Then, an impurity-doped conductive layer, for example, a polysilicon layer (not shown), is formed on the entire surface of the resultant structure. Then, the polysilicon layer is patterned to form a gate electrode 611. Though not shown in FIG. 20, a gate spacer can be formed on the sidewalls of the gate electrode 611 after the gate electrode 611 is formed.

Thereafter, n⁺-type source/drain regions 607s and 607d are formed in the high voltage p-type MOS transistor 631, and two p⁺-type diffusion regions 606 are formed in the low voltage region 610, by a typical p-type impurity ion implantation and diffusion process. Then, an n⁺-type diffusion region 606 is formed in the high voltage p-type MOS transistor 631 by an n-type impurity ion implantation and diffusion process.

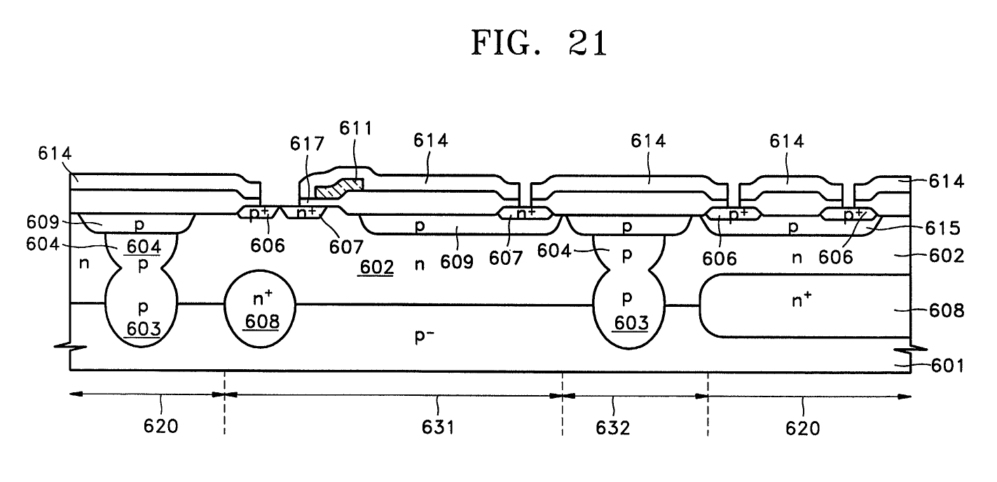

Referring to FIG. 21, an insulating layer is formed on the entire surface of the resultant structure. Then, the insulating layer is patterned using a predetermined etch mask layer pattern. Formed insulating layer patterns 614 have apertures which expose the n⁺-type diffusion region 606 and the p⁺-type source/drain regions 607s and 607d in the high voltage p-type MOS transistor 631 and apertures which expose the two p⁺-type diffusion regions 606 in the low voltage region 610.

Thereafter, as shown in FIG. 7, a source electrode 612, a drain electrode 613 and a conductive layer 616 are formed. Here, the drain electrode 613 extends across the high breakdown voltage isolation region 632 and contacts one p⁺-type diffusion region 606 in the low voltage region 610, and the conductive layer 616 contacts the other p⁺-type diffusion region 606. In this way, the high voltage semiconductor device having a high breakdown voltage isolation region according to another embodiment of the present invention is completed.

In the high voltage semiconductor device having a high breakdown voltage isolation region, according to an embodiment of the present invention, an n-type epitaxial layer and an n⁺-type buried layer are formed, as described above. Accordingly, during breakdown of a DMOS transistor, impact ionization first occurs on the n⁺-type buried layer before it occurs on the surface region of a semiconductor substrate, thereby improving the reliability of the semiconductor device. Also, although the high breakdown voltage isolation region having a double isolation structure made up of a p-type buried layer and a p-type impurity region is not easily depleted since it has a greater concentration than that in conventional semiconductor devices, the potential lines between two regions are overlapped by each other, which prevents a high electrical field from being applied. Therefore, a sufficient breakdown voltage can be guaranteed only if the high breakdown voltage isolation region does not have an extremely high concentration. Furthermore, various device having good characteristics can be formed within a high voltage region, and this high voltage semiconductor device can be easily applied to high breakdown voltage products.

In the high voltage semiconductor device having a high breakdown voltage isolation region, according to another embodiment of the present invention, an n-type epitaxial layer and an n⁺-type buried layer are formed, as described above. Accordingly, during breakdown of a high voltage p-type MOS transistor, impact ionization first occurs on the n⁺-type buried layer before it occurs on the surface region of a semiconductor substrate, thereby improving the reliability of the semiconductor device. Also, although the high breakdown voltage isolation region having a double isolation structure made up of a p-type buried layer and a first p-type diffusion region is not easily depleted since it has a greater concentration than that in conventional semiconductor devices, the potential lines between two regions are overlapped by each other, which prevents a high electrical field from being applied. Therefore, a total breakdown voltage is increased. Furthermore, various device having good characteristics can be formed within a low voltage region, and this high voltage semiconductor device can be easily applied to high breakdown voltage products.

What is claimed is:

1. A high voltage semiconductor device having a high breakdown voltage isolation region and a junction termination including a lateral DMOS transistor between a high voltage region and a low voltage region, the device comprising:
a semiconductor substrate of a first conductivity type;
an epitaxial layer of a second conductivity type formed on the semiconductor substrate;
a first diffusion region of a first conductivity type for isolation formed in each of the lateral DMOS transistor and the high breakdown voltage isolation region;
a second diffusion region of a first conductivity type formed on the surface portion of the epitaxial layer in the lateral DMOS transistor to be adjacent to the first diffusion region of the first conductivity type;
a source region of a second conductivity type formed within the second diffusion region of the first conductivity type;
a drain region of a second conductivity type formed on the surface of the epitaxial layer in the lateral DMOS transistor to be isolated a predetermined interval apart from the source region of a second conductivity type;
a resistance unit formed in the high voltage region for transferring a signal from the lateral DMOS transistor to the high voltage region;
a gate insulating layer formed on the channel region of the second diffusion region of a first conductivity type in the lateral DMOS transistor;
a gate electrode formed on the gate insulating layer;
a source electrode formed to contact the source region of a second conductivity type; and
a drain electrode which contacts the drain region of a second conductivity type and is formed to be connected to the resistance unit via the high breakdown voltage isolation region.

2. The high voltage semiconductor device of claim 1, wherein the first diffusion region comprises:
a buried layer of a first conductivity type formed on the interface between the semiconductor substrate and the epitaxial layer in the lateral DMOS transistor and the high breakdown voltage isolation region; and
an impurity region of a first conductivity region formed on the buried layer of a first conductivity type to be adjacent to the buried layer and the second diffusion region of a first conductive type.

3. The high voltage semiconductor device of claim 1, further comprising a buried layer of a second conductivity type formed between the semiconductor substrate and the epitaxial layer within the high voltage region.

4. The high voltage semiconductor device of claim 3, wherein the impurity concentration in the buried layer of a second conductivity type is higher than the impurity concentration in the epitaxial layer of a second conductivity type.

5. The high voltage semiconductor device of claim 1, further comprising a buried layer of a second conductivity type formed between the semiconductor substrate and the epitaxial layer within the lateral DMOS transistor to be isolated a predetermined interval apart from the drain region of a second conductivity type.

6. The high voltage semiconductor device of claim 5, wherein the impurity concentration in the buried layer of a second conductivity type is higher than the impurity concentration in the epitaxial layer of a second conductivity type.

7. The high voltage semiconductor device of claim 1, further comprising a top region of a first conductivity type formed between the source region of a second conductivity type and the drain region of a second conductivity type, on the surface of the epitaxial layer of the lateral DMOS transistor.

8. The high voltage semiconductor device of claim 1, further comprising a top region of a first conductivity type formed on the surface of the epitaxial layer in the high breakdown voltage isolation region to be adjacent to the first diffusion region of a first conductivity type.

9. The high voltage semiconductor device of claim 1, wherein the resistance unit comprises:
a third diffusion region of a first conductivity type formed on the surface of the epitaxial layer in the high voltage region; and
two high concentration regions of a first conductivity type formed on the surface of the third diffusion region of a first conductivity type so that the two high concentration regions are isolated from each other.

10. The high voltage semiconductor device of claim 9, wherein one of the two high concentration regions of a first conductivity type is connected to the drain electrode.

11. The high voltage semiconductor device of claim 10, further comprising a conductive layer connected to the high voltage region while contacting the other high concentration region of a second conductivity type not connected to the drain electrode.

12. The high voltage semiconductor device of claim 1, wherein the first conductivity type is a p type, and the second conductivity type is an n type.

13. A high voltage semiconductor device having a high voltage MOS transistor of a first conductivity type and a high breakdown voltage isolation region between a high voltage region and a low voltage region, the device comprising:
a semiconductor substrate of a first conductivity type;
an epitaxial layer of a second conductivity type formed on the semiconductor substrate;
a first diffusion region of a first conductivity type for isolation formed in each of the high voltage region and the high breakdown voltage isolation region;
a buried layer of a second conductivity type formed between the semiconductor substrate and the epitaxial layer in each of the high voltage MOS transistor and the low voltage region;
a source region of a first conductivity type formed a predetermined interval apart over the second buried layer of a second conductivity type in the high voltage MOS transistor;
a drain region of a first conductivity type formed on the surface of the epitaxial layer in the high voltage MOS transistor to be isolated a predetermined interval from the source region of a first conductivity type;
a resistance unit formed in the low voltage region for transferring a signal from the high voltage MOS transistor to the low voltage region;
a gate insulating layer formed on a channel region on the surface of the epitaxial layer in the high voltage MOS transistor;
a gate electrode formed on the gate insulating layer;
a source electrode formed to contact the source region of a first conductivity type; and
a drain electrode which contacts the drain region of a first conductivity type and is formed to be connected to the resistance unit via the high breakdown voltage isolation region.

14. The high voltage semiconductor device of claim 13, wherein the first diffusion region comprises:
a buried layer of a first conductivity type formed on the interface between the semiconductor substrate and the epitaxial layer in the high voltage MOS region and the high breakdown voltage isolation region; and
an impurity region of a first conductivity region formed on the buried layer of a first conductivity type.

15. The high voltage semiconductor device of claim 13, wherein the impurity concentration in the buried layer of a second conductivity type is higher than the impurity concentration in the epitaxial layer of a second conductivity type.

16. The high voltage semiconductor device of claim 13, further comprising a top region of a first conductivity type formed on the surface of the epitaxial layer of the high voltage MOS transistor so that it is isolated a predetermined interval from the source region of a first conductivity type and covers the drain region of a first conductivity type.

17. The high voltage semiconductor device of claim 13, wherein the resistance unit comprises:
a second diffusion region of a first conductivity type formed on the surface of the epitaxial layer in the low voltage region; and
two high concentration regions of a first conductivity type formed on the surface of the second diffusion region of a first conductivity type so that the two high concentration regions are isolated from each other.

18. The high voltage semiconductor device of claim 17, wherein one of the two high concentration regions of a first conductivity type is connected to the drain electrode.

19. The high voltage semiconductor device of claim 18, further comprising a conductive layer connected to the high voltage region while contacting the other high concentration region of a second conductivity type not connected to the drain electrode.

20. The high voltage semiconductor device of claim 13, wherein the first conductivity type is a p type, and the second conductivity type is an n type.
